(19) United States
(12) Patent Application Publication
(10) Pub. No.: US 2020/0152274 A1
(43) Pub. Date: May 14, 2020

(54) DATA STORAGE APPARATUS, OPERATING METHOD THEREOF, AND STORAGE SYSTEM INCLUDING DATA STORAGE APPARATUS

(71) Applicant: SK hynix Inc., Icheon-si Gyeonggi-do (KR)

(72) Inventors: Bum Seok PARK, Icheon-si Gyeonggi-do (KR); Deung Kak YOO, Icheon-si Gyeonggi-do (KR)

(73) Assignee: SK hynix Inc., Icheon-si Gyeonggi-do (KR)

(21) Appl. No.: 16/443,153

(22) Filed: Jun. 17, 2019

(30) Foreign Application Priority Data
Nov. 12, 2018 (KR) 10-2018-0137902

(51) Int. Cl. G11C 16/10; G06F 3/06; G11C 11/56

(52) U.S. Cl. CPC G11C 16/105; G06F 3/0656; G11C 11/5635; G06F 3/0688; G06F 3/0619

(57) ABSTRACT

A data storage apparatus includes a controller configured to control data input to and output from a storage according to a request transmitted from a host apparatus, a buffer memory configured to store data transmitted and received between the host apparatus and the storage, and the storage including a plurality of memory cells and a verification component configured to verify a state of a target memory cell before write data is programmed in the target memory cell while the write data is transmitted from the host apparatus in response to a write request of the host apparatus.

### CROSS-REFERENCES TO RELATED APPLICATION

The present application claims priority under 35 U.S.C. § 119(a) to Korean application number 10-2018-0137902, filed on Nov. 12, 2018, in the Korean Intellectual Property Office, which is incorporated herein by reference in its entirety.

### BACKGROUND

### 1. Technical Field

Various embodiments may generally relate to a semiconductor integrated apparatus, and more particularly, to a data storage apparatus, an operating method thereof, and a storage system having the data storage apparatus.

### 2. Related Art

Storage apparatuses may be coupled to a host apparatus and perform a data input/output operation according to a request of the host apparatus. The storage apparatuses may employ various storage media to store data.

The storage apparatuses may include apparatuses configured to store data in magnetic discs such as a hard disc drive (HDD) and apparatuses configured to store data in semiconductor memory devices (particularly, nonvolatile memory devices) such as a solid state drive (SDD) or a memory card.

Storage media employing flash memories have the advantages of a large amount of capacity, non-volatility, low cost, low power consumption, high data processing rate, and the like.

The reliability of the storage media may depend on the performance of accurate programing of the write-requested data therein and accurate reading of the data stored therein.

### SUMMARY

In an embodiment of the present disclosure, a data storage apparatus may include: a controller configured to control data input to and output from a storage according to a request transmitted from a host apparatus; a buffer memory configured to store data transmitted and received between the host apparatus and the storage; and the storage including a plurality of memory cells and a verification component configured to verify a state of a target memory cell before write data is programmed in the target memory cell while the write data is transmitted from the host apparatus in response to a write request of the host apparatus.

In an embodiment of the present disclosure, a data storage apparatus may include: a controller configured to control data input to and output from a storage according to a request transmitted from a host apparatus; a buffer memory configured to store data transmitted and received between the host apparatus and the storage; and the storage including a plurality of memory cells and a verification component configured to verify a state of a target memory cell to be written to in parallel with the verification of the state of the target memory cell while write data is transmitted from the host apparatus to the storage in response to a write request from the host apparatus.

In an embodiment of the present disclosure, an operating method of a data storage apparatus which may include a controller configured to control data input to and output from a storage according to a request transmitted from a host apparatus, a buffer memory configured to store data transmitted and received between the host apparatus and the storage, and the storage including a verification component and a plurality of memory cells, the method may include: verifying a state of a target memory cell with the verification component before write data is programmed in the target memory cell while the write data is transmitted from the host apparatus in response to a write request of the host apparatus.

In an embodiment of the present disclosure, a storage system may include: a host apparatus; and a data storage apparatus which includes a controller configured to control data input to and output from the storage according to a request transmitted from the host apparatus, a buffer memory configured to store data transmitted and received between the host apparatus and the storage, and the storage including a verification component and a plurality of memory cells. The verification component may be configured to verify a state of a target memory cell before write data is programmed in the target memory cell while the write data is transmitted from the host apparatus in response to a write request of the host apparatus.

### BRIEF DESCRIPTION OF THE DRAWINGS

FIG. 1 is a diagram illustrating a configuration of a data storage apparatus according to an embodiment of the present disclosure;

FIG. 2 is a diagram illustrating a configuration of a storage according to an embodiment of the present disclosure;

FIG. 3 is a diagram illustrating a configuration of a controller according to an embodiment of the present disclosure;

FIG. 4 is a diagram illustrating a configuration of a write control component according to an embodiment of the present disclosure;

FIGS. 5 and 6 are diagrams explaining an operating method of a data storage apparatus according to an embodiment of the present disclosure;

FIGS. 7 and 8 are diagrams explaining an operating method of a data storage apparatus according to an embodiment of the present disclosure;

FIGS. 9 and 10 are diagrams explaining an operating method of a data storage apparatus according to an embodiment of the present disclosure; and

FIG. 11 is a diagram illustrating a configuration of a page buffer circuit according to an embodiment of the present disclosure.

FIG. 12 is a diagram illustrating a data storage system in accordance with an embodiment.

FIG. 13 and FIG. 14 are diagrams illustrating a data processing system in accordance with an embodiment.

FIG. 15 is a diagram illustrating a network system including a data storage device in accordance with an embodiment.

### DETAILED DESCRIPTION

Various embodiments will be described in with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the disclosure as defined in the appended claims.

The embodiments are described herein with reference to cross-section and/or plan illustrations. However, embodiments should not be construed as limiting. Although a few embodiments will be shown and described, it will be appreciated by those of ordinary skill in the art that changes may be made in these embodiments without departing from the principles and spirit of the disclosure.

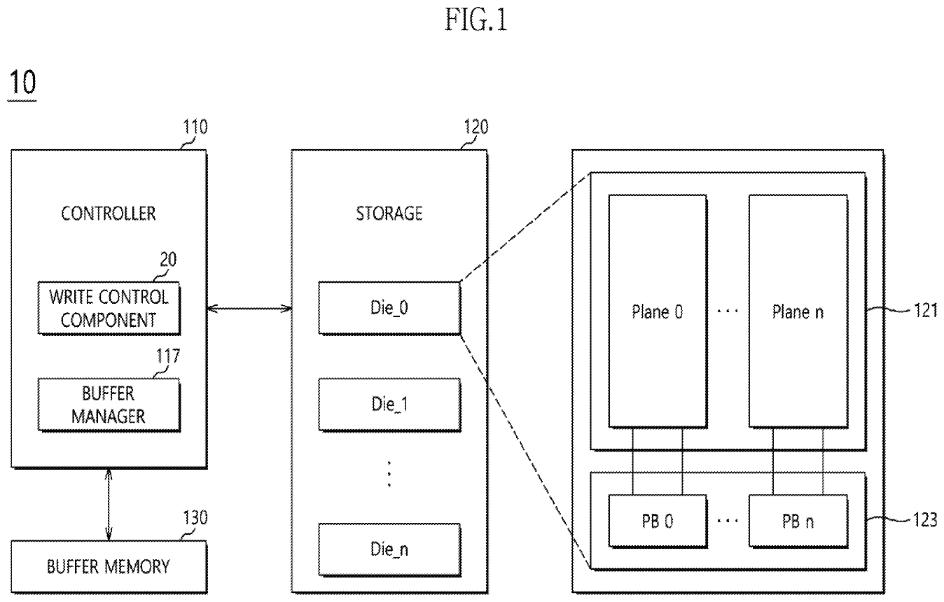

FIG. 1 is a configuration diagram illustrating a data storage apparatus according to an embodiment.

Referring to FIG. 1, a data storage apparatus 10 according to an embodiment may include a controller 110, a storage 120, and a buffer memory 130.

The controller 110 may control the storage 120 in response to a request of a host apparatus (not shown). For example, the controller 110 may control data to be programmed in the storage 120 according to a program (write) request of the host apparatus. Further, the controller 110 may provide data written in the storage 120 to the host apparatus in response to a read request of the host apparatus. The controller 110 may include a write control component 20 and a buffer manager 117.

The storage 120 may program data or output programmed data according to control of the controller 110. A description of the data storage 120 will be described later.

The buffer memory 130, which in some embodiments may be a buffer memory, may serve as a space which temporarily stores data when the data storage apparatus 10 performs a series of operations of programming or reading data in conjunction with a host apparatus and the like. The example that the buffer memory 130 is arranged in the outside of the controller 110 is illustrated in FIG. 1, but this is not limited thereto and the buffer memory 130 may be arranged in the inside of the controller 110.

The buffer memory 130 may be controlled with the buffer manager 117.

The buffer manager 117 may divide the buffer memory 130 into a plurality of regions (slots) and allocate or release the regions to temporarily store data. The allocation of the region may refer to a state that data has been stored in the corresponding region or data stored in the corresponding region is valid. The release of the region may refer to a state that data is not stored in the corresponding region or data stored in the corresponding region is invalid.

In an embodiment, as a program completion signal is transmitted from the storage 120, the buffer manager 117 may release a buffer region (slot) in which program-completed unit data is cached. The buffer manager 117 may receive new program data from a host apparatus and store the new program data in the released buffer region.

The write control component 20 may be configured to schedule a write processing method and a write processing timing in response to a write request of a host apparatus and write data in the storage 120 according to a scheduling result.

The storage 120 may be configured of a volatile memory device or a nonvolatile memory device. In an embodiment, the storage 120 may be implemented using a memory device selected from various nonvolatile memory devices such as an electrically erasable and programmable read only memory (EEPROM), a NAND flash memory, a NOR flash memory, a phase-change random access memory (PRAM), a resistive RAM (ReRAM), a ferroelectric RAM (FRAM), and a spin torque transfer magnetic RAM (STT-RAM). The storage 120 may include a plurality of dies Die_0 to Die_n, a plurality of chips, or a plurality of packages. Further, the storage 120 may be configured of a single level cell (SLC) in which a single bit data (for example, 1-bit data) is to be stored in one memory cell and a multilevel cell (MLC) in which multi-bit data (i.e., multiple bit data) is to be stored in one memory cell.

In an embodiment, the storage 120, for example, each die may include a memory cell array 121 and a page buffer circuit 123.

The memory cell array 121 may include a plurality of memory cells coupled between a plurality of word lines and a plurality of bit lines. The memory cell array 121 may be divided into a plurality of planes Plane 0 to Plane n.

The page buffer circuit 123 may include a plurality of page buffer circuits PB 0 to PB n. In an embodiment, the page buffer circuit 123 may be provided in such a manner that the plurality of page buffer circuits PB 0 to PBn correspond to the plurality of planes Plane 0 to Plane n.

In a write operation, data provided from a host apparatus may be cached in the buffer memory 130 with the controller 110 and then written in the memory cell array 121 via the page buffer circuit 123. In a read operation, data read from the memory cell array 121 may be loaded into the page buffer circuit 123 and then provided to the host apparatus through the controller 110.

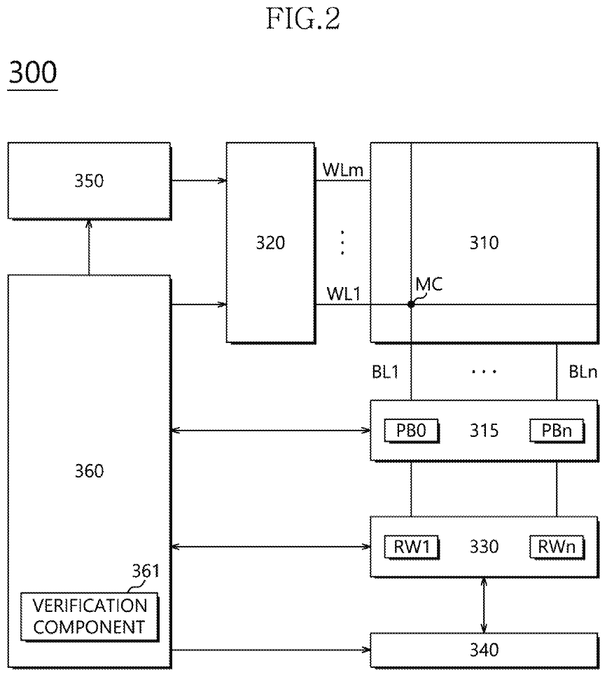

FIG. 2 is a configuration diagram illustrating a storage according to an embodiment.

Referring to FIG. 2, a storage 300 may include a memory cell array 310, a page buffer circuit 315, a row decoder 320, a data read/write block 330, a column decoder 340, a voltage generator 350, and a control logic 360.

The memory cell array 310 may be divided into at least one or more planes and include a plurality of memory cells MC arranged in regions in which word lines WL1 to WLm and bit lines BL1 to BLn cross each other.

The memory cell array 310 may include a three-dimensional (3D) memory array. The 3D memory array may have a structure including a NAND string which has a vertical directionality with respect to a plan surface of a semiconductor substrate and at least one memory cell thereof is vertically located over another memory cell. However, the structure of the 3D memory array is not limited thereto and it is obvious that any memory array structure having a vertical directionality as well as a horizontal directionality and having a high-integration degree may be selectively applied to the 3D memory array.

The row decoder 320 may be coupled to the memory cell array 310 through the word lines WL1 to WLm. The row decoder 320 may be operated according to control of the control logic 360. The row decoder 320 may decode an address provided from an external apparatus (not shown). The row decoder 320 may select and drive the word lines WL1 to WLm based on a decoding result. For example, the row decoder 320 may provide word line voltages provided from the voltage generator 350 to the word lines WL1 to WLm.

The data read/write block 330 may be coupled to the memory cell array 310 through the page buffer circuit 315 and the bit lines BL1 to BLn. The data read/write block 330 may include read/write circuits RW1 to RWn corresponding to the bit lines BL1 to BLn. The data read/write block 330 may be operated according to control of the control logic 360. The data read/write block 330 may be operated as a write driver or a sense amplifier according to an operation mode. For example, the data read/write block 330 may be operated as the write driver configured to store data provided from an external apparatus in the memory cell array 310 in the write operation. In another example, the data read/write block 330 may be operated as the sense amplifier configured to read out data from the memory cell array 310 in the read operation.

The column decoder 340 may be operated according to control of the control logic 360. The column decoder 340 may decode an address provided from an external apparatus. The column decoder 340 may couple the read/write circuits RW1 to RWn of the data read/write block 330 corresponding to the bit lines BL1 to BLn and data input/output (I/O) lines (or data I/O buffers) based on a decoding result.

The voltage generator 350 may generate voltages used in a background operation of the nonvolatile memory device 300 as the storage 300. The voltages generated through the voltage generator 350 may be applied to memory cells of the memory cell array 310. For example, a program voltage generated in a program operation may be applied to a word line of memory cells on which the program operation is to be performed. In another example, an erase voltage generated in an erase operation may be applied to well-regions of memory cells on which the erase operation is to be performed. In another example, a read voltage generated in a read operation may be applied to a word line of memory cells on which the read operation is to be performed.

The control logic 360 may control an overall operation of the nonvolatile memory device 300 based on a control signal provided from an external apparatus. For example, the control logic 360 may control the read, write (program), and erase operations of the nonvolatile memory device 300.

In an embodiment, the control logic 360 may include a verification component 361.

The verification component 361 may be configured to verify a state of a memory cell to be written before write data of a host apparatus is programmed in the memory cell array 121 or 310 at the same time while the write data of the host apparatus is transmitted in response to a write request of the host apparatus. Here, the operation of verifying the state of the memory cell may be an operation of transferring data of a target memory cell to the page buffer 315 and comparing the data of the target memory cell and an erase level.

Before the verification component 361 verifies the erase state of the target memory cell, the verification component 361 may erase the target memory cell. The verification component 361 may erase the target memory cell and verify the erase state of the target memory cell again when it is determined that the target memory cell is not in the erase state or in a state other than the erase state through the verification of the erase state of the target memory cell.

In another aspect, the verification component 361 may be configured to verify the state (for example, erase state) of a memory cell to be written to in parallel with the verification of the state of the target memory cell while the write data is transmitted from the host apparatus to the storage 300 in response to the write request from the host apparatus.

In an embodiment, the verification component 361 may be configured to verify an erase state of a memory cell in at least a partial section of an entire section that the write data transmitted from the host apparatus is stored in the page buffer circuit 315 via the buffer memory 130 and then programmed in the memory cell array 310 in response to the write request of the host apparatus.

A flash memory device among the memory devices which may constitute the storage 300 needs to be erased before data is programmed in the memory cell. When the data is programmed in the non-erased memory cell due to an error of the controller 110, the mistake of the user, and the like, the desired data may not be stored due to the over programming.

Accordingly, the reliability of the data storage apparatus 10 may be improved by verifying the erase state of the memory cell with the verification component 361 and writing data only in the memory cell of the erase state before the data is written in the memory cell.

In particular, in the present technology, without sparing of the time for verifying the erase state of a memory cell to be written, while the data to be written is transferred to the storage 120, the erase state of the target memory cell may be verified. For example, the write data transmitted from the host apparatus may be transferred to the storage 120 and at the same time or in parallel, the erase state of the target memory cell may be verified. Accordingly, the over programming may be prevented without the use of a separate resource or the generation of latency.

In an embodiment, the verification component 361 may be configured to verify the erase state for the target memory cell while the write data transmitted from the host apparatus is stored in the buffer memory 130, while the write data transmitted from the host apparatus is stored in the page buffer circuit 315 via the buffer memory 130, or while the data stored in the buffer memory 130 is transferred to the page buffer circuit 315. When the target memory cell is in the erase state, the write operation may be continuously performed. When the target memory cell is not in the erase state, information indicating the occurrence of write fail may return to the host apparatus. Alternatively, when the target memory cell is not in the erase state, the verification component may request the erase of the corresponding memory cell through the control logic 360.

As described above, in the present technology, to store the write data in the target memory cell, the verification component 361 may verify the erase state of the target memory cell during the write data transfer process. When the target memory cell is not in the erase state, the verification component 361 may process the write operation to be failed or perform the write operation on a corresponding memory cell after the erase of the corresponding memory cell and thus the over programming may be prevented.

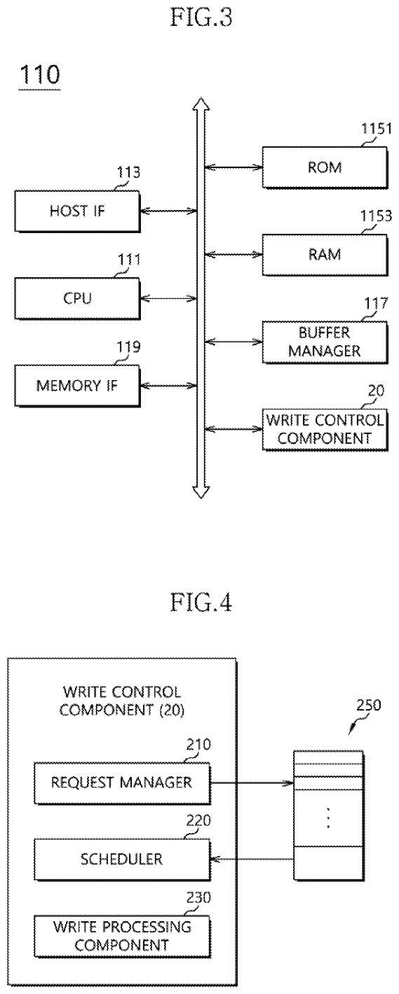

FIG. 3 is a configuration diagram illustrating a controller according to an embodiment.

Referring to FIG. 3, the controller 110 according to an embodiment may include a central processing unit (CPU) 111, a host interface 113, a read-only memory (ROM) 1151, a random access memory (RAM) 1153, the buffer manager 117, a memory interface 119, and the write control component 20.

The CPU 111 may be configured to transfer various control information required for the data read or write operation with respect to the storage 120 to the host interface 113, the RAM 1151, the buffer manager 117, and the memory interface 119. In an embodiment, the CPU 111 may be operated according to firmware provided for the various operations of the data storage apparatus 10. In an embodiment, the CPU 111 may perform functions of a flash translation layer (FTL) for performing garbage collection, address mapping, ware leveling, and the like which manage the storage 120, a function of detecting and correcting errors of data read out from the storage 120, and the like.

The host interface 113 may, through control of the CPU 111, receive a command and a clock signal from a host apparatus and provide a communication channel for controlling data input/output. In particular, the host interface 113 may provide a physical connection between the host apparatus and the data storage apparatus 10. The host interface 113 may provide interfacing with the data storage apparatus 10 in response to a bus format of the host apparatus. The bus format of the host apparatus may include at least one of standard interface protocols such as secure digital, universal serial bus (USB), multi-media card (MMC), embedded MMC (eMMC), personal computer memory card international association (PCMCIA), parallel advanced technology attachment (PATA), serial advanced technology attachment (SATA), small computer system interface (SCSI), serial attached SCSI (SAS), peripheral component interconnection (PCI), PCI Express (PCI-E), and universal flash storage (UFS).

The ROM 1151 may store program codes, for example, firmware or software required for an operation of the controller 110 and store code data and the like which are used by the program codes.

The RAM 1153 may store data required for an operation of the controller 110 or data generated through the controller 110.

The CPU 111 may control a booting operation of the data storage apparatus 10 by loading a booting code stored in the storage 120 or the ROM 1151 into the RAM 1153 in a booting operation.

The buffer manager 117 may be configured to manage a use state of the buffer memory 130, for example, use states of the regions (slots) in the buffer memory 130. In an embodiment, the buffer manager 117 may divide the buffer memory 130 into a plurality of regions (slots) and allocate or release the regions to temporarily store data.

In an embodiment, the buffer manager 117 may release the buffer region (slot) in which the program-completed unit data is cached in response to the program completion signal transmitted to the storage 120. Then, the buffer manager 117 may allocate the released buffer region to store new unit data provided from the host apparatus.

The memory interface 119 may provide a communication channel for receiving and transmitting signals between the controller 110 and the storage 120. The memory interface 119 may write (program) data temporarily stored in the buffer memory 130 in the storage 120 according to control of the CPU 111. The memory interface 119 may transfer and temporarily store data read out from the storage 120 to and in the buffer memory 130.

The write control component 20 may be configured to schedule the write processing method and the write processing timing in response to the write command, the address, and the write data of the host apparatus and write data in the storage 120 according to a scheduling result.

FIG. 4 is a configuration diagram illustrating the write control component 20 according to an embodiment.

Referring to FIG. 4, the write control component 20 may include a request manager 210, the scheduler 220, a write processing component 230, and a command register 250.

The request manager 210 may store the write command by allocating an empty space of the command register 250 as the write command is provided from the host apparatus. The write command may be stored in the command register 250 in input order. The write request of the host apparatus may include a logical address. The controller 110 may convert the logical address included in the write command of the host apparatus into a physical address and provide the converted physical address to the request manager 210 and the request manager 210 may store the command and the physical address corresponding thereto in the command register 250. The request manager 210 may delete the process-completed command from the command register 250.

The request manager 210 may manage processing statuses according to the commands of the host apparatus, for example, as tags, but this is not limited thereto.

The scheduler 220 may schedule the write processing method, the write processing timing, and the like with reference to the operation status of the data storage 10 in response to the write command. In an embodiment, the scheduler 220 may determine the write processing timing based on a predetermined command processing priority. In an embodiment, the scheduler 220 may select a write mode (program mode) of a normal program mode and a cache program mode based on a size of data to be written.

In an embodiment, the normal program mode may refer to a writing method which completes the write operation of first data with respect to the memory cell array 121 of the storage 120 and then stores second data to be written next in the buffer memory 130.

The cache program mode may refer to a writing method which has stored the second data to be written next in the buffer memory 130 while writing the first data in the memory cell array 121 of the storage 120.

The write processing component 230 may control the control logic 360 of the storage 120 or 300 to write data in the target memory cell based on the scheduling result of the scheduler 220.

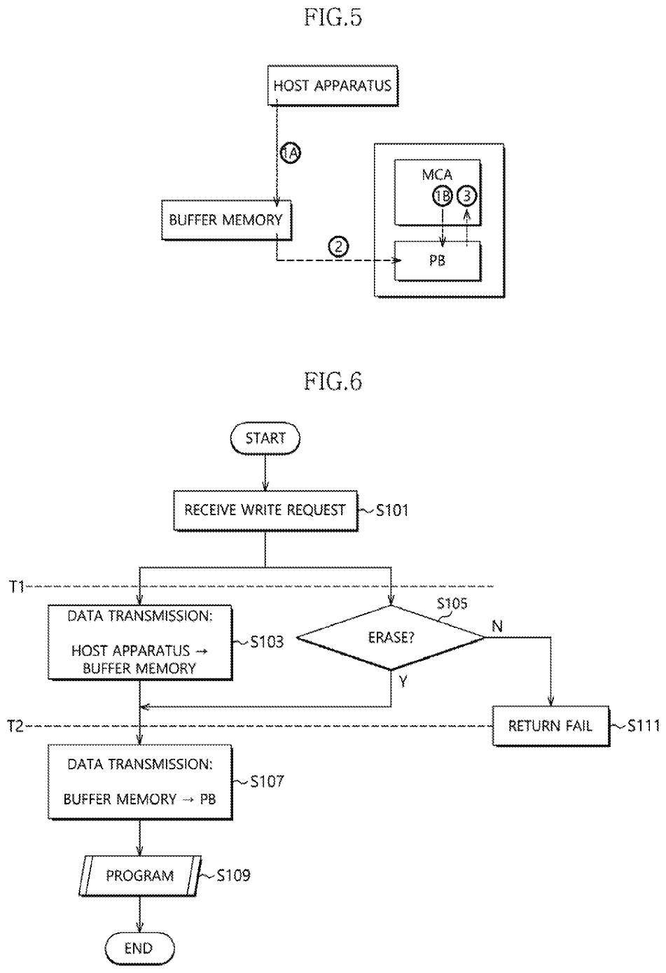

FIGS. 5 and 6 are diagrams explaining an operation method of a data storage apparatus according to an embodiment.

Referring to FIGS. 5 and 6, a host apparatus may transmit a write request including a write command, an address, and write data to the data storage apparatus 10. The data storage apparatus 10 may receive the write request from the host apparatus (S101).

The write data of the host apparatus may be transmitted from the host apparatus to the buffer memory 130 (\textcircled{1A}, S103). At the same time, the verification component 361 of the control logic 360 in the storage 120 or 300 may verify a state of a target memory cell (\textcircled{1B}, S105). In an embodiment, the verification component 361 may determine an erase state of the target memory cell by reading out data of the target memory cell to the page buffer circuit 123 and comparing the data of the target memory cell and an erase level.

When the target memory cell is in the erase state as a verifying result (S105:Y), the write data cached in the buffer memory 130 may be transferred to the page buffer circuit (PB) 123 or 315 (\textcircled{2}, S107). The data latched in the page buffer circuit 123 or 315 may be programmed into the target memory cell ((\textcircled{3}, S109). In an embodiment, the program operation may be a process of changing a threshold voltage of the target memory cell to a desired level by applying preset program voltages or preset program inhibit voltages to the word line and the bit line of the memory cell array.

When the target memory cell is not in the erase state as the verifying result (S105:N), the verification component 361 may provide information indicating the occurrence of write fail to the host apparatus (fail return) (S111). In an embodiment, when the target memory cell is not in the erase state (S105:N), the verification component 361 may request the erase of the corresponding memory cell through the control logic 360.

As described above, the state of the target memory cell may be verified while the write data is cached in the buffer memory 130 (first point in time T1 to a second point in time T2) and thus the over programming may be prevented without the occurrence of separate latency.

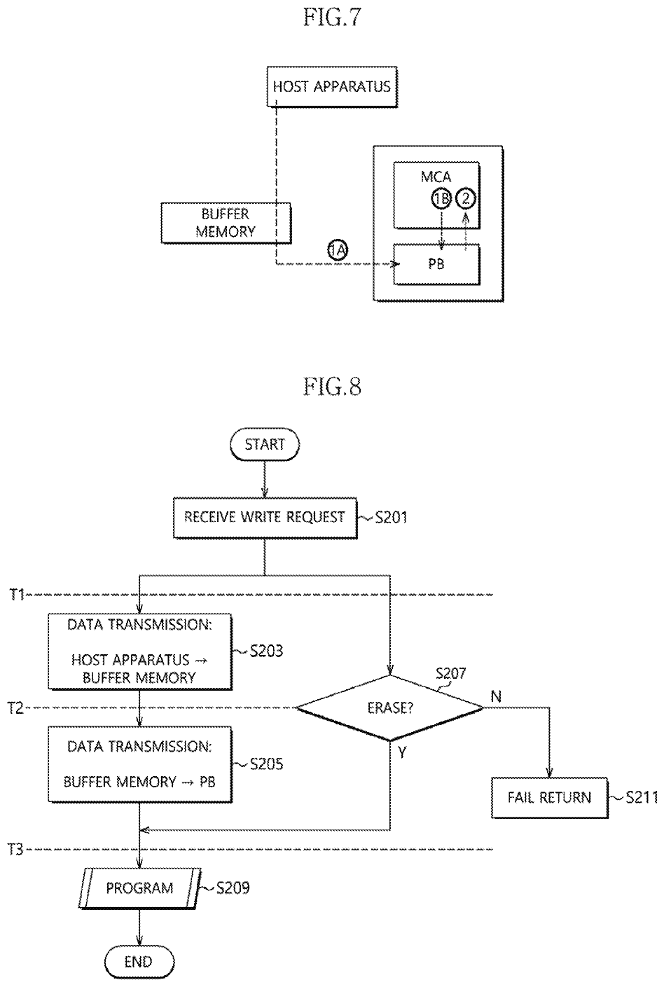

FIGS. 7 and 8 are diagrams explaining an operation method of a data storage apparatus according to an embodiment.

Referring to FIGS. 7 and 8, a host apparatus may transmit a write request including a write command, an address, and write data to the data storage apparatus 10. The data storage apparatus 10 may receive the write request from the host apparatus (S201).

The write data of the host apparatus may be transmitted from the host apparatus to the page buffer circuit (PB) 123 or 315 via the buffer memory 130 (\textcircled{1A}, S203 to S205). During a section that the write data is transferred to the page buffer circuit 123 or 315, the verification component 361 of the control logic 360 in the storage 120 or 300 may verify a state of a target memory cell (\textcircled{1B}, S207). To verify the state of the memory cell, the verification component 361 may determine an erase state of the target memory cell by reading out data of the target memory cell to the page buffer circuit 123 or 315 and comparing the data of the target memory cell and an erase level.

When the target memory cell is in the erase state as a verifying result (S207:Y), the write data latched in the page buffer circuit 123 or 315 may be programmed in the target memory cell (\textcircled{2}, S209). In an embodiment, the program operation may be a process of changing a threshold voltage of the target memory cell to a desired level by applying preset program voltages or preset program inhibit voltages to the word line and the bit line of the memory cell array.

When the target memory cell is not in the erase state as the verifying result (S207:N), the verification component 361 may provide information indicating the occurrence of write fail to the host apparatus (fail return) (S211). In an embodiment, when the target memory cell is not in the erase state (S207:N), the verification component 361 may request the erase of the corresponding memory cell through the control logic 360.

As described above, the state of the target memory cell may be verified while the write data is latched in the page buffer circuit 123 or 315 (second point in time T2 to third point in time T3) via the buffer memory 120 (T1 to T2) and thus the over programming may be prevented without the occurrence of separate latency. In an embodiment, the verification component 361 may verify the state of the target memory cell in at least a partial section of a time section that the write data is transmitted to the page buffer circuit 315 or 123 via the buffer memory 130. For example, but not limited to, the verification component 361 may verify the state of the target memory cell between a partial section of time between a first point in time T1 and a third point in time T3. For example, but not limited to, the verification component 361 may verify the state of the target memory cell between a partial section of time between a second point in time T2 to a third point of time T3 within the first point in time T1 and a third point in time T3.

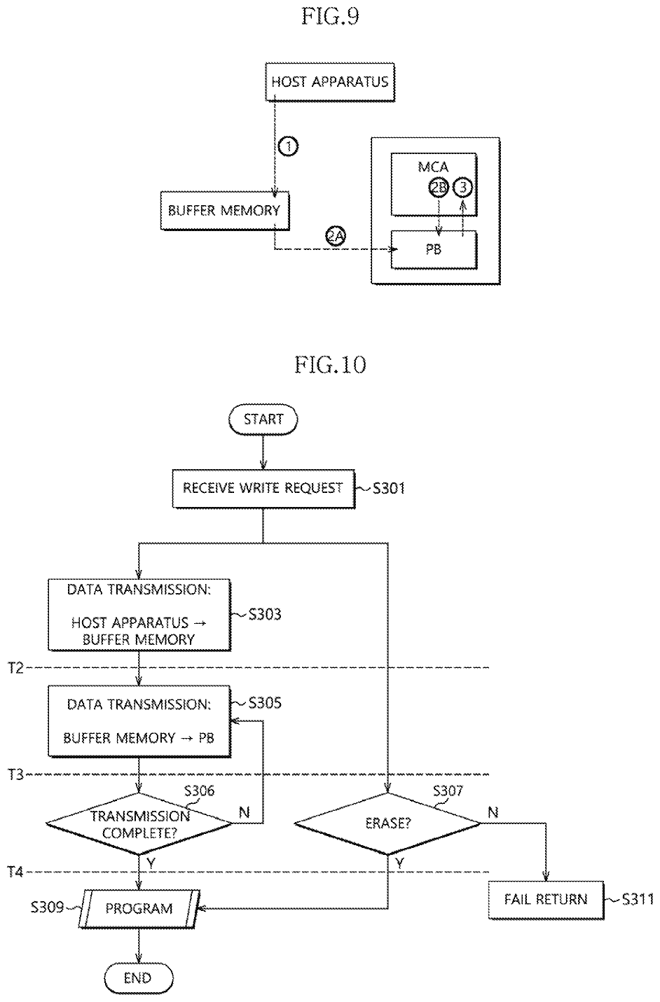

FIGS. 9 and 10 are diagrams explaining an operation method of a data storage apparatus according to an embodiment.

Referring to FIGS. 9 and 10, a host apparatus may transmit a write request including a write command, an address, and write data to the data storage apparatus 10 (S3101). The data storage apparatus 10 may receive the write request from the host apparatus (S301).

The write data of the host apparatus may be transmitted from the host apparatus to the buffer memory 130 and cached in the buffer memory 130 (\textcircled{1}, S303).

The write data cached in the buffer memory 130 may be transferred to the page buffer circuit (PB) 123 or 315 (\textcircled{2A}, S305).

When a memory cell constituting the storage 120 is a memory cell configured to store multi bit-data, the write data configured to multi bit-data may be sequentially transferred to the page buffer circuit 123 or 315. The controller 110 may determine whether or not all the bit data of the data to be written (write data) are transferred to the page buffer circuit 123 or 315 (S306) and when it is determined that all the bit data of the write data are not transferred to the page buffer circuit 123 or 315 (S306: N), it may proceed to operation S305 of transferring data cached in the buffer memory 130 to the page buffer circuit 123 or 315 (S305) and the controller 110 may control all the bit data of the write data to be latched in the page buffer circuit 123.

During a section that all the bit data of the write data are transferred to the page buffer circuit 123 or 315, the verification component 361 in the control logic 360 of the storage 120 or 300 may verify the state of the target memory cell (\textcircled{2B}, S307). To verify the state of the memory cell, the verification component 361 may determine whether or not the target memory cell is in the erase state by reading out data of the target memory cell to the page buffer circuit 123 or 315 and comparing the read data and an erase level.

When the target memory cell is in the erase state as a verifying state (S307:Y), the multi-bit data latched in the page buffer circuit 123 or 315 may be programmed in the target memory cell (\textcircled{3}, S309). In an embodiment, the program operation may be a process of changing a threshold voltage of the target memory cell to a desired level by applying preset program voltages or preset program inhibit voltages to the word line and the bit line of the memory cell array.

When the target memory cell is not in the erase state as the verifying result (S307:N), the verification component 361 may provide information indicating the occurrence of write fail to the host apparatus (fail return) (S311). In an embodiment, when the target memory cell is not in the erase state (S307:N), the verification component 361 may request the erase of the corresponding memory cell through the control logic 360.

In an embodiment, the memory cell may be configured to store 3-bit data. In the write operation, least significant bit (LSB) data, central significant bit (CSB) data, and most significant bit (MSB) data may be sequentially transferred from the buffer memory 130 to the page buffer circuit 123 or 315. Then, the verification component 361 may verify the state of the target memory cell before transferring the CBS data to the page buffer circuit 123 or 315 after transferring the LSB data to the page buffer circuit 123 or 315 or before transferring the MSB data to the page buffer circuit 123 or 315 after transferring the CBS data to the page buffer circuit 123 or 315, but this is not limited thereto.

As described above, the state of the target memory cell may be verified while bit data of the multi-bit write data are sequentially latched from the buffer memory 130 to the page buffer circuit 123 or 315 (second point in time T2 to a fourth point in time T4) and thus the over programming may be prevented without the occurrence of separate latency. In an embodiment, the verification component 361 may verify the state of the target memory cell in at least a partial section of a time section that the write data is transmitted to the page buffer circuit 315 or 123 via the buffer memory 130. For example, but not limited to, the verification component 361 may verify the state of the target memory cell between a partial section of time between a second point in time T2 and a fourth point in time T4. For example, but not limited to, the verification component 361 may verify the state of the target memory cell between a partial section of time between a third point in time T3 to a fourth point of time T4 within the second point in time T2 and a fourth point in time T4.

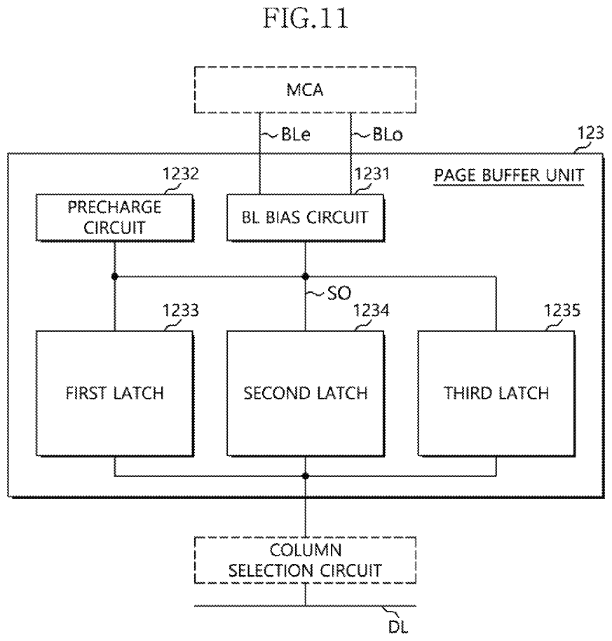

FIG. 11 is a configuration diagram illustrating a page buffer circuit according to an embodiment.

Referring to FIG. 11, the page buffer circuit 123 according to an embodiment may include a bit line bias circuit 1231, a precharge circuit 1232, and a plurality of latches 1233, 1234, and 1235.

The bit line bias circuit 1231 may be configured to supply voltages predetermined according to an operation mode to a pair of bit lines (even bit line BLe and odd bit line BLo) extending from a memory cell array MCA.

A potential of a sensing node SO may be determined according to a program state of a selected memory cell in the read operation.

The precharge circuit 1232 may be configured to precharge the sensing node SO.

The first latch 1233 may be configured to receive data read out from the second latch 1234 and output the received data to the outside through a data line DL coupled to a column selection circuit.

The second latch 1234 may be configured to store a read operation result value from a memory cell.

The third latch 1235 may be configured to receive data read out from the second latch 1234.

The configuration of the page buffer circuit 123 is not limited to the configuration of FIG. 11. The page buffer circuit 123 may be selected from the configurations including a plurality of latches, but this is not limited thereto. The example that the verification of the state of the target memory cell is performed in parallel with the transfer of the data of the buffer memory 130 to the page buffer circuit 123 may be implemented through the page buffer circuit including the plurality of latches.

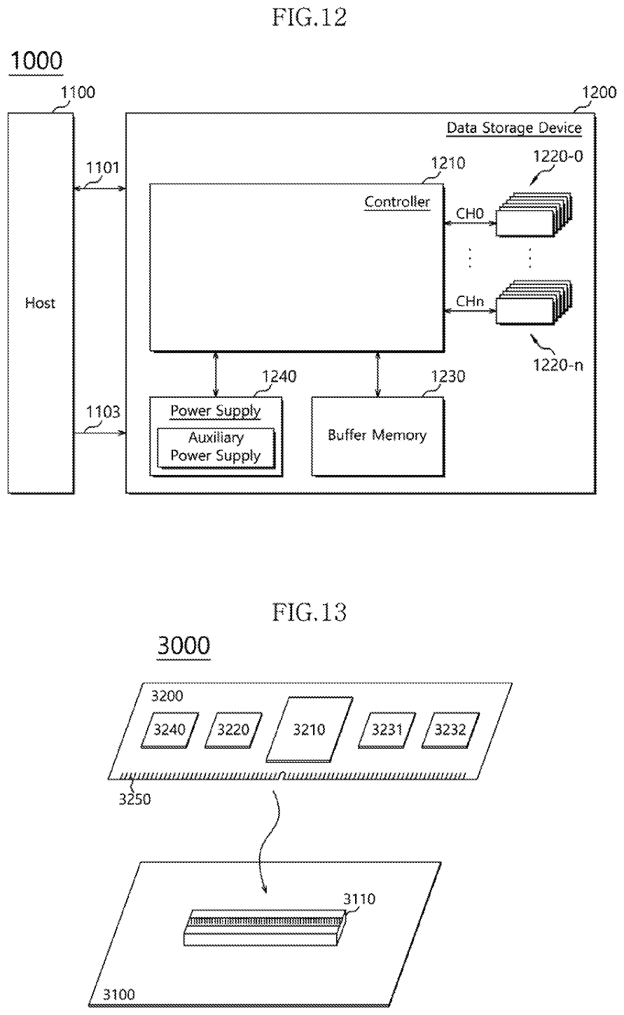

FIG. 12 is a diagram illustrating a data storage system in accordance with an embodiment.

Referring to FIG. 12, the data storage 1000 may include a host device 1100 and the data storage device 1200. In an embodiment, the data storage device 1200 may be configured to a solid state drive (SSD).

The data storage device 1200 may include a controller 1210, a plurality of nonvolatile memory devices 1220-0 to 1220-n, a buffer memory device 1230, a power supply 1240, a signal connector 1101, and a power connector 1103.

The controller 1210 may control general operations of the data storage device 1200. The controller 1210 may include a host interface, a controller, a random access memory used as a working memory, an error correction code (ECC) circuit, and a memory interface. In an embodiment, the controller 1210 may configured by controllers 110 as shown is FIG. 1, FIG. 3 and FIG. 4.

The host device 1100 may exchange a signal with the data storage device 1200 through the signal connector 1101. The signal may include a command, an address, data, and so forth.

The controller 1210 may analyze and process the signal received from the host device 1100. The controller 1210 may control operations of internal function blocks according to a firmware or a software for driving the data storage device 1200.

The buffer memory device 1230 may temporarily store data to be stored in at least one of the nonvolatile memory devices 1220-0 to 1220-n. Further, the buffer memory device 1230 may temporarily store the data read from at least one of the nonvolatile memory devices 1220-0 to 1220-n. The data temporarily stored in the buffer memory device 1230 may be transmitted to the host device 1100 or at least one of the nonvolatile memory devices 1220-0 to 1220-n according to control of the controller 1210.

The nonvolatile memory devices 1220-0 to 1220-n may be used as storage media of the data storage device 1200. The nonvolatile memory devices 1220-0 to 1220-n may be coupled with the controller 1210 through a plurality of channels CH1 to CHn, respectively. One or more nonvolatile memory devices may be coupled to one channel. The nonvolatile memory devices coupled to each channel may be coupled to the same signal bus and data bus.

The power supply 1240 may provide power inputted through the power connector 1103, to the inside of the data storage device 1200. The power supply 1240 may include an auxiliary power supply. The auxiliary power supply may supply power to allow the data storage device 1200 to be normally terminated when a sudden power-off occurs. The auxiliary power supply may include large capacity capacitors.

The signal connector 1101 may be configured by various types of connectors depending on an interface scheme between the host device 1100 and the data storage device 1200.

The power connector 1103 may be configured by various types of connectors depending on a power supply scheme of the host device 1100.

FIG. 13 is a diagram illustrating a data processing system in accordance with an embodiment. Referring to FIG. 13, the data processing system 3000 may include a host device 3100 and the memory system 3200.

The host device 3100 may be configured in the form of a board such as a printed circuit board. Although not shown, the host device 3100 may include internal function blocks for performing the function of a host device.

The host device 3100 may include a connection terminal 3110 such as a socket, a slot or a connector. The memory system 3200 may be mounted to the connection terminal 3110.

The memory system 3200 may be configured in the form of a board such as a printed circuit board. The memory system 3200 may be referred to as a memory module or a memory card. The memory system 3200 may include a controller 3210, a buffer memory device 3220, nonvolatile memory devices 3231 and 3232, a power management integrated circuit (PMIC) 3240, and a connection terminal 3250.

The controller 3210 may control general operations of the memory system 3200. The controller 3210 may be configured in the same manner as the controllers 110 as shown in FIG. 1, FIG. 3 and FIG. 4.

The buffer memory device 3220 may temporarily store data to be stored in the nonvolatile memory devices 3231 and 3232. Further, the buffer memory device 3220 may temporarily store the data read from the nonvolatile memory devices 3231 and 3232. The data temporarily stored in the buffer memory device 3220 may be transmitted to the host device 3100 or the nonvolatile memory devices 3231 and 3232 according to control of the controller 3210.

The nonvolatile memory devices 3231 and 3232 may be used as storage media of the memory system 3200.

The PMIC 3240 may provide the power inputted through the connection terminal 3250, to the inside of the memory system 3200. The PMIC 3240 may manage the power of the memory system 3200 according to control of the controller 3210.

The connection terminal 3250 may be coupled to the connection terminal 3110 of the host device 3100. Through the connection terminal 3250, signals such as commands, addresses, data and so forth and power may be transferred between the host device 3100 and the memory system 3200. The connection terminal 3250 may be configured into various types depending on an interface scheme between the host device 3100 and the memory system 3200. The connection terminal 3250 may be disposed on any one side of the memory system 3200.

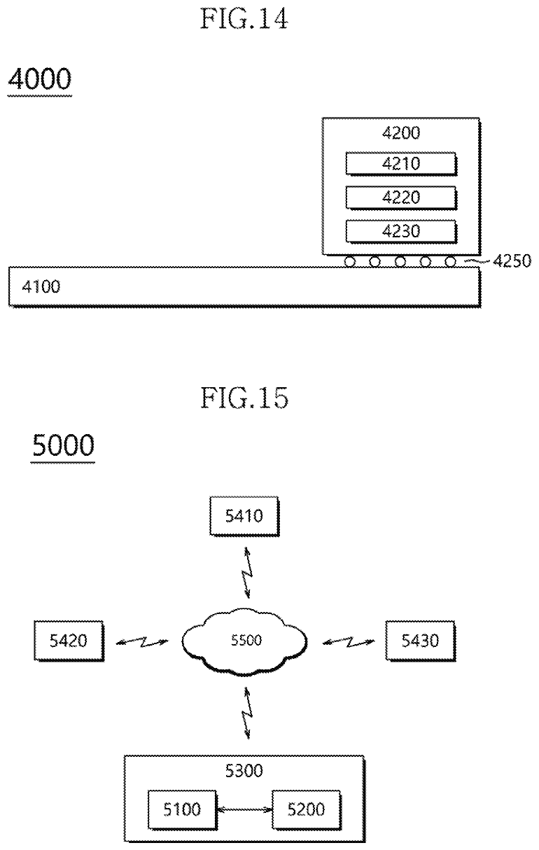

FIG. 14 is a diagrams illustrating a data processing system in accordance with an embodiment. Referring to FIG. 14, the data processing system 4000 may include a host device 4100 and the memory system 4200.

The host device 4100 may be configured in the form of a board such as a printed circuit board. Although not shown, the host device 4100 may include internal function blocks for performing the function of a host device.

The memory system 4200 may be configured in the form of a surface-mounting type package. The memory system 4200 may be mounted to the host device 4100 through solder balls 4250. The memory system 4200 may include a controller 4210, a buffer memory device 4220, and a nonvolatile memory device 4230.

The controller 4210 may control general operations of the memory system 4200. The controller 4210 may be configured in the same manner as the controllers 110 as shown in FIG. 1, FIG. 3 and FIG. 4.

The buffer memory device 4220 may temporarily store data to be stored in the nonvolatile memory device 4230. Further, the buffer memory device 4220 may temporarily store the data read from the nonvolatile memory device 4230. The data temporarily stored in the buffer memory device 4220 may be transmitted to the host device 4100 or the nonvolatile memory device 4230 according to control of the controller 4210.

The nonvolatile memory device 4230 may be used as the storage medium of the memory system 4200.

FIG. 15 is a diagram illustrating a network system including a data storage device in accordance with an embodiment. Referring to FIG. 15, the network system 5000 may include a server system 5300 and a plurality of client systems 5410 to 5430 which are coupled through a network 5500.

The server system 5300 may service data in response to requests from the plurality of client systems 5410 to 5430. For example, the server system 5300 may store the data provided from the plurality of client systems 5410 to 5430. For another example, the server system 5300 may provide data to the plurality of client systems 5410 to 5430.

The server system 5300 may include a host device 5100 and the memory system 5200. The memory system 5200 may be configured by the memory systems 10 shown in FIG. 1, the data storage devices 1200 shown in FIG. 12, the memory systems 3200 shown in FIG. 13 or the memory systems 4200 shown in FIG. 14.

While various embodiments have been described above, it will be understood to those skilled in the art that the embodiments described are examples only. Accordingly, the data storage device, the operating method thereof and the storage system including the same described herein should not be limited based on the described embodiments.

The above described embodiments are intended to illustrate and not to limit the disclosure. Various alternatives and equivalents are possible. The disclosure is not limited by the embodiments described herein. Nor is the disclosure limited to any specific type of semiconductor device. Other additions, subtractions, or modifications are obvious in view of the present disclosure and are intended to fall within the scope of the appended claims.

What is claimed is:

1. A data storage apparatus comprising:
a controller configured to control data input to and output from a storage according to a request transmitted from a host apparatus;
a buffer memory configured to store data transmitted and received between the host apparatus and the storage; and
the storage including a plurality of memory cells and a verification component configured to verify a state of a target memory cell before write data is programmed in the target memory cell while the write data is transmitted from the host apparatus in response to a write request of the host apparatus.

2. The data storage apparatus of claim 1, wherein the verification component is configured to verify whether or not the state of the target memory cell is in an erase state.

3. The data storage apparatus of claim 2, wherein the verification component is configured to verify the erase state of the target memory cell after erasing the target memory cell.

4. The data storage apparatus of claim 2, wherein the verification component is configured to verify the erase state of the target memory cell again after erasing the target memory cell when the target memory cell is in a state other than the erase state.

5. The data storage apparatus of claim 1, wherein the storage comprises a page buffer circuit configured to latch data read out from a memory cell or data to be written in a memory cell, and
the verification component is configured to compare the data of the target memory cell and an erase level by transferring the data of the target memory cell to the page buffer circuit.

6. The data storage apparatus of claim 1, wherein the verification component is configured to verify the state of the target memory cell while the write data is stored in the buffer memory.

7. The data storage apparatus of claim 1, wherein the storage comprises a page buffer circuit configured to latch data read out from a memory cell or data to be written in a memory cell, and
the verification component is configured to verify the state of the target memory cell while write data stored in the buffer memory is stored in the page buffer circuit.

8. The data storage apparatus of claim 1, wherein the storage comprises a page buffer circuit configured to latch data read out from a memory cell or data to be written in a memory cell,
the write data is configured of multiple bits of data, and
the verification component is configured to verify the state of the target memory cell while bits of data of the write data are sequentially transmitted to the page buffer circuit.

9. The data storage apparatus of claim 1, wherein the storage comprises a page buffer circuit configured to latch data read out from a memory cell or data to be written in a memory cell, and
the verification component is configured to verify the state of the target memory cell in at least a partial section of a time section that the write data is transmitted to the page buffer circuit via the buffer memory.

10. A data storage apparatus comprising:
a controller configured to control data input to and output from a storage according to a request transmitted from a host apparatus;
a buffer memory configured to store data transmitted and received between the host apparatus and the storage; and
the storage including a plurality of memory cells and a verification component configured to verify a state of a target memory cell to be written to in parallel with the verification of the state of the target memory cell while write data is transmitted from the host apparatus to the storage in response to a write request from the host apparatus.

11. The data storage apparatus of claim 10, wherein the verification component is configured to verify whether or not the state of the target memory cell is in an erase state.

12. The data storage apparatus of claim 10, wherein the storage comprises a page buffer circuit configured to latch data read out from a memory cell or data to be written into a memory cell, and
the verification component is configured to verify the state of the target memory cell in at least a partial section of a time section that the write data is transmitted to the page buffer circuit via the buffer memory.

13. The data storage apparatus of claim 10, wherein the storage comprises a page buffer circuit configured to latch data read out from a memory cell or data to be written in a memory cell,
the write data is configured of multiple bits of data, and
the verification component is configured to verify the state of the target memory cell while bits of data of the write data are sequentially transmitted to the page buffer circuit.

14. The data storage apparatus of claim 13, wherein the write data comprises lease significant bit (LSB) data, central significant bit (CSB) data, and most significant bit (MSB) data, and
the verification component is configured to verify the state of the target memory cell before transferring the CSB data to the page buffer after transferring the LSB data to the page buffer circuit or before transferring the MSB to the page buffer circuit after transferring the CSB data to the page buffer circuit.

15. An operating method of a data storage apparatus which comprises a controller configured to control data input to and output from a storage according to a request transmitted from a host apparatus, a buffer memory configured to store data transmitted and received between the host apparatus and the storage, and the storage including a verification component and a plurality of memory cells, the method comprising:
verifying a state of a target memory cell with the verification component before write data is programmed in the target memory cell after transferring the write data from the host apparatus in response to a write request of the host apparatus.

16. The method of claim 15, wherein the verifying comprises verifying whether or not the state of the target memory cell is in an erase state with the verification component.

17. The method of claim 16, wherein the verifying comprises verifying the erase state of the target memory cell after erasing the target memory cell.

18. The method of claim 16, wherein the verifying comprises verifying the erase state of the target memory cell again after erasing target memory cell when the target memory cell is in a state other than the erase state.

19. The method of claim 15, wherein the storage comprises a page buffer circuit configured to latch data read out from a memory cell or data to be written in a memory cell, and
the verifying comprises transferring data of the target memory cell to the buffer memory and comparing the data of the target memory cell and an erase level with the verification component.

20. The method of claim 15, wherein the verifying comprises verifying the state of the target memory cell with the verification component while the write data is stored in the buffer memory.

21. The method of claim 15, wherein the storage comprises a page buffer circuit configured to latch data read out from a memory cell or data to be written in a memory cell, and
the verifying comprises verifying the state of the target memory cell with the verification component while write data stored in the buffer memory is stored in the page buffer circuit.

22. The method of claim 15, wherein the storage comprises a page buffer circuit configured to latch data read out from a memory cell or data to be written in a memory cell,
the write data is configured of multiple bits of data, and
the verifying comprises verifying the state of the target memory cell with the verification component while bits of data of the write data are sequentially transmitted to the page buffer circuit.

23. The method of claim 15, wherein the storage comprises a page buffer circuit configured to latch data read out from a memory cell or data to be written in a memory cell, and
the verifying is performed with the verification component in at least a partial section of a time section that the write data is transmitted to the page buffer circuit via the buffer memory.

24. A storage system comprising:
a host apparatus; and
a data storage apparatus which comprises a controller configured to control data input to and output from the storage according to a request transmitted from the host apparatus, a buffer memory configured to store data transmitted and received between the host apparatus and the storage, and the storage including a verification component and a plurality of memory cells,
wherein the verification component is configured to verify a state of a target memory cell before write data is programmed in the target memory cell after transferring the write data from the host apparatus in response to a write request of the host apparatus.

25. The storage system of claim 24, wherein the verification component is configured to verify whether or not the state of the target memory cell is in an erase state.

26. The storage system of claim 25, wherein the verification component is configured to verify the erase state of the target memory cell after erasing the target memory cell.

27. The storage system of claim 25, wherein the verification component is configured to verify the erase state of the target memory cell again after erasing the target memory cell when the target memory cell is in a state other than the erase state.

28. The storage system of claim 24, wherein the verification component is configured to verify the state of the target memory cell while the write data is stored in the buffer memory.

29. The storage system of claim 24, wherein the storage comprises a page buffer circuit configured to latch data read out from a memory cell or data to be written in a memory cell, and
the verification component is configured to verify the state of the target memory cell while write data stored in the buffer memory is stored in the page buffer circuit.

30. The storage system of claim 24, wherein the storage comprises a page buffer circuit configured to latch data read out from a memory cell or data to be written in a memory cell,
the write data is configured of multiple bits of data, and
the verification component is configured to verify the state of the target memory cell while bits of data of the write data are sequentially transmitted to the page buffer circuit.
